(19) United States
(12) Patent Application Publication
(10) Pub. No.: US 2019/0074848 A1
(43) Pub. Date: Mar. 7, 2019

(54) KEYBOARD APPARATUS

(71) Applicants: LITE-ON ELECTRONICS (GUANGZHOU) LIMITED, GUANGZHOU (CN); Lite-On Technology Corporation, Taipei (TW)

(72) Inventor: Kuo-Fu Kuo, Taipei (TW)

(73) Assignees: LITE-ON ELECTRONICS (GUANGZHOU) LIMITED, GUANGZHOU (CN); Lite-On Technology Corporation, Taipei (TW)

(21) Appl. No.: 15/927,093

(22) Filed: Mar. 21, 2018

(30) Foreign Application Priority Data
Sep. 7, 2017 (CN) 201710799292.3

(51) Int. Cl. H03M 11/00; H03M 11/20; G06F 3/023; H03K 17/98

(52) U.S. Cl. CPC H03M 11/003; H03K 17/98; G06F 3/023; H03M 11/20

(57) ABSTRACT

A keyboard apparatus including a key module and a detection circuit is provided. The key module includes a plurality of keys, a plurality of scan lines and a plurality of return lines. The scan lines and the return lines are crossed to each other and respectively coupled to the keys. The detection circuit detects a plurality of return voltages of the return lines and generates a plurality of detection signals accordingly so as to indicate that a switch of each of the keys is at an on state or at an off state. The detection circuit includes a plurality of P-type transistors. A first terminal of each P-type transistor is coupled to a ground terminal, a control terminal of each P-type transistor is directly coupled to a corresponding one of the return lines, and a second terminal of each P-type transistor generates and outputs one of the detection signals.

### CROSS-REFERENCE TO RELATED APPLICATION

This application claims the priority benefit of China application serial no. 201710799292.3, filed on Sep. 7, 2017. The entirety of the above-mentioned patent application is hereby incorporated by reference herein and made a part of this specification.

### BACKGROUND

### Technical Field

The disclosure relates to a keyboard apparatus and particularly relates to a keyboard apparatus that prevents the occurrence of ghost key phenomenon and achieves low manufacturing costs.

### Description of Related Art

For the purpose of avoiding the use of too many wirings, which leads to the increase of manufacturing costs of the keyboard itself and the inconvenience in actual assembly, conventional keyboard apparatuses are mainly designed as a key matrix. For a keyboard apparatus designed as a key matrix, ghost key phenomenon are prone to occur due to physical characteristics of the key matrix itself. Herein Taiwan Patent No. 1485991 specifies the main reason for the occurrence of ghost key phenomenon. In order to prevent the occurrence of ghost key phenomenon, the general solution, for example, is to increase the size of the key matrix or to separate each key by a diode. However, such kind of approach also significantly increases the manufacturing costs of the keyboard apparatus.

Therefore, Taiwan Patent No. 1485991 provides a ghost key detecting circuit to prevent the occurrence of ghost key phenomenon and reduce the manufacturing costs. Hereinafter, with reference to FIG. 1, FIG. 1 is a schematic view showing a ghost key detecting circuit 100 disclosed by Taiwan Patent No. 1485991. The ghost key detecting circuit 100 includes scan lines S1 and S2 (each having a resistance R_{C}), return lines R1 and R2, switching components 305a-305d (each having a predetermined resistance R_{B}), resistors 310a and 310b (each having a resistance R_{A}), a level detection circuit 315 and a processor 320, wherein the scan lines S1 and S2 and the return lines R1 and R2 are crossed to each other and respectively coupled to the switching components 305a-305d to form a double cross structure as shown in FIG. 1. A first terminal of the switching component 305a and a first terminal of the switching component 305b are coupled to the scan line S1. A second terminal of the switching component 305a and a second terminal of the switching component 305b are coupled to the return line R1 and the return line R2 respectively. A first terminal of the switching component 305c and a first terminal of the switching component 305d are coupled to the scan line S2. A second terminal of the switching component 305c and a second terminal of the switching component 305d are coupled to the return line R1 and the return line R2 respectively. Besides, the second terminal of the switching component 305a and the second terminal of the switching component 305c are coupled to the resistor 310a via the return line R1, and the second terminal of the switching component 305b and the second terminal of the switching component 305d are coupled to the resistor 310b via the return line R2. Another end of the resistor 310a and another end of the resistor 310b are coupled to a power terminal V_{DD}. The level detection circuit 315 is coupled to the return lines R1 and R2 for detecting measuring voltages of the return lines R1 and R2 so as to indicate the state (an off state or an on state) of each of the switching components 305a-305d corresponding to each of the return lines R1 and R2 and each of the scan lines S1 and S2.

As shown in FIG. 1, the level detection circuit 315 includes transistors Q1-Q4 and resistors R_{U1} and R_{U2}. A base of the transistor Q1 is coupled to the return line R1, and an emitter of the transistor Q1 is coupled to a ground terminal GND. A collector of the transistor Q1 and a base of the transistor Q2 are coupled to each other and are coupled to an end of the resistor R_{U1}. Another end of the resistor R_{U1} is coupled to the power terminal V_{DD}. An emitter of the transistor Q2 is coupled to the ground terminal GND. A collector of the transistor Q2 is configured to generate a logic level signal S_{L1}. Similarly, a base of the transistor Q3 is coupled to the return line R2, and an emitter of the transistor Q3 is coupled to the ground terminal GND. A collector of the transistor Q3 and a base of the transistor Q4 are coupled to each other and are coupled to an end of the resistor R_{U2}. Another end of the resistor R_{U2} is coupled to the power terminal V_{DD}. An emitter of the transistor Q4 is coupled to the ground terminal GND. A collector of the transistor Q4 is configured to generate a logic level signal S_{L2}.

When the measuring voltage of the return line R1 is greater than or equal to a threshold voltage of the transistor Q1, the transistor Q1 is turned on and a collector voltage of the transistor Q1 is pulled down to the potential of the ground terminal GND. Since an across voltage between the base and the emitter of the transistor Q2 does not exceed a threshold voltage of the transistor Q2, the transistor Q2 is not turned on. At this time, the logic level signal S_{L1} is at a high logic level. Therefore, the processor 320 could determine that the key corresponding to one of the switching components 305a and 305c on the return line R1 is not pressed based on the fact that the logic level signal S_{L1} is at a high logic level.

Conversely, when the measuring voltage of the return line R1 is smaller than the threshold voltage of the transistor Q1, the transistor Q1 is not turned on. As a result, the across voltage between the base and the emitter of the transistor Q2 exceeds the threshold voltage of the transistor Q2 such that the transistor Q2 is turned on. At this time, the logic level signal S_{L1} is at a low logic level. Therefore, the processor 320 could determine that the key corresponding to one of the switching components 305a and 305c on the return line R1 is pressed based on the fact that the logic level signal S_{L1} is at a low logic level.

Besides, the operations of the transistors Q3 and Q4 are similar to the operations of the transistors Q1 and Q2, so repeated descriptions thereof are omitted here. Accordingly, depending on whether the transistor Q1 or the transistor Q3 is turned on or not, the transistor Q2 or the transistor Q4 may output signals at different logic levels to correctly indicate whether the key is pressed or not, thereby preventing the occurrence of ghost key phenomenon.

Since each return line (such as the return line R1) needs to detect whether the key on the return line (the return line R1) is pressed or not by using two transistors (such as the transistors Q1 and Q2) and one resistor (such as the resistor R_{U1}), once the number of the return lines is increased, the numbers of the transistors and resistors used in the level detection circuit 315 are bound to greatly increase. As a result, the manufacturing costs of the keyboard apparatus are also greatly increased. Consequently, one of the major issues in this field is how to reduce the manufacturing costs of the keyboard apparatus without causing the occurrence of ghost key phenomenon.

### SUMMARY

Accordingly, the disclosure provides a keyboard apparatus that not only prevents the occurrence of ghost key phenomenon but also reduces the manufacturing costs.

The keyboard apparatus of the disclosure includes a key module and a detection circuit. The key module includes a plurality of keys, a plurality of scan lines and a plurality of return lines. The scan lines and the return lines are crossed to each other and respectively coupled to the keys. The detection circuit is coupled to the return lines for detecting a plurality of return voltages of the return lines, and generates a plurality of detection signals accordingly so as to indicate that a switch of each of the keys is at an on state or at an off state. The detection circuit includes a plurality of P-type transistors. A first terminal of each of the P-type transistors is coupled to a ground terminal, a control terminal of each of the P-type transistors is directly coupled to a corresponding one of the return lines, and a second terminal of each of the P-type transistors generates and outputs a corresponding one of the detection signals.

In an embodiment of the disclosure, the P-type transistor is a PNP bipolar junction transistor.

In an embodiment of the disclosure, the P-type transistor is a P-type metal oxide semiconductor transistor.

In an embodiment of the disclosure, when the return voltage of the corresponding one of the return lines is greater than or equal to a reference voltage, the switch of the key coupled between the corresponding one of the return lines and an activated scan line of the plurality of scan lines is at an off state, wherein the reference voltage is associated with a threshold voltage of the P-type transistor.

In an embodiment of the disclosure, when the return voltage of the corresponding one of the return lines is smaller than a reference voltage, the switch of the key coupled between the corresponding one of the return lines and an activated scan line of the plurality of scan lines is at an on state, wherein the reference voltage is associated with a threshold voltage of the P-type transistor.

In an embodiment of the disclosure, the keyboard apparatus further includes a processing circuit. The processing circuit is coupled to the detection circuit to receive the detection signals and determines whether each of the keys is pressed or not according to the detection signals.

In an embodiment of the disclosure, the processing circuit is further coupled to the scan lines to sequentially activate one of the scan lines, and determines whether each of the keys on the activated scan line is pressed or not according to the detection signals.

Based on the foregoing, the keyboard apparatus in the embodiment of the disclosure could prevent the occurrence of ghost key phenomenon. Besides, in the keyboard apparatus from the embodiment of the disclosure, for the keyboard apparatus to determine if the key on the return line is pressed or not, only one single transistor is required to perform the level detection operation in each return line. Consequently, it is possible to effectively reduce the manufacturing costs of the keyboard apparatus.

To make the aforementioned and other features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic view showing a conventional ghost key detecting circuit.

FIG. 2 is a schematic view showing a keyboard apparatus according to an embodiment of the disclosure.

FIG. 3 is a schematic view showing an equivalent circuit of the keyboard apparatus as shown in FIG. 2.

FIG. 4 is a schematic view showing an equivalent circuit of the keyboard apparatus in FIG. 3 when one key is pressed.

FIG. 5 is a schematic view showing an equivalent circuit of the keyboard apparatus in FIG. 3 when three keys are pressed and one key is not pressed.

FIG. 6A is a schematic view showing an equivalent circuit of the keyboard apparatus in FIG. 5 when a scan line in FIG. 5 is activated.

FIG. 6B is a schematic view showing an equivalent circuit of the keyboard apparatus in FIG. 5 when another scan line in FIG. 5 is activated.

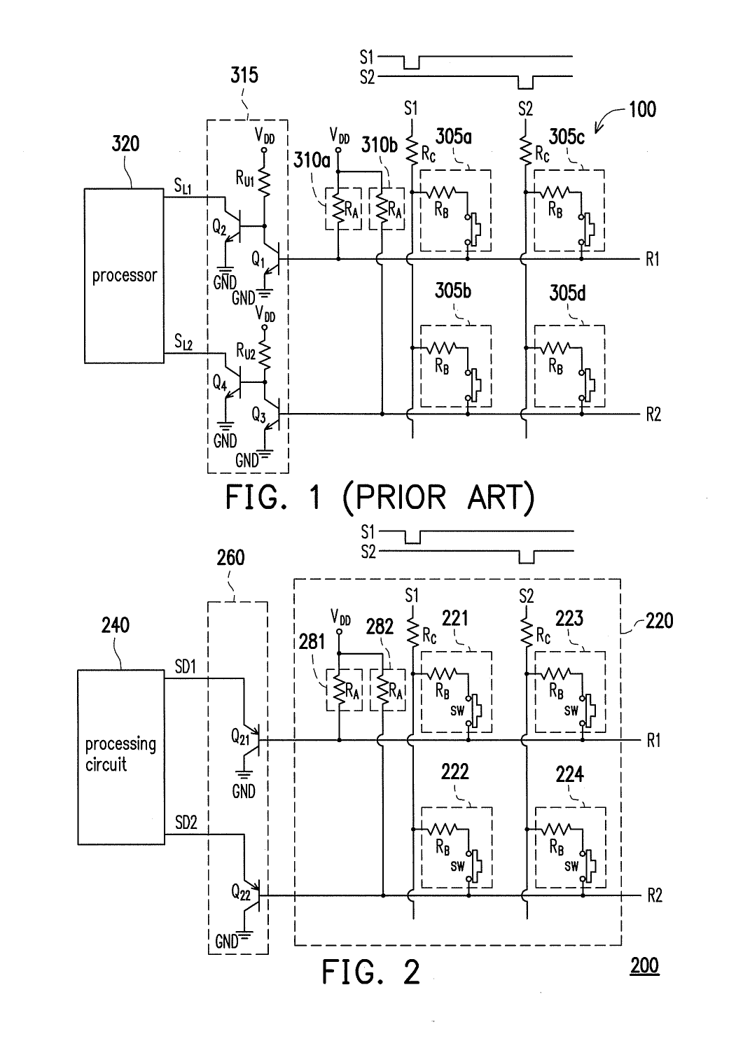

### DESCRIPTION OF THE EMBODIMENTS

Descriptions of the disclosure are given with reference to the exemplary embodiments illustrated by the accompanying drawings. In addition, wherever possible, identical or similar reference numerals stand for identical or similar elements/components in the drawings and embodiments.

Hereinafter, with reference to FIG. 2, FIG. 2 is a schematic view showing a keyboard apparatus 200 according to an embodiment of the disclosure. The keyboard apparatus 200 includes a key module 220, a detection circuit 260 and a processing circuit 240, but the disclosure is not limited thereto. The key module 220 includes (M×N) keys, N scan lines and M return lines, wherein M may be a positive integer greater than or equal to 2, and N may also be a positive integer greater than or equal to 2. However, for the convenience of illustration, in this embodiment, it is assumed that M and N are both 2, and embodiments where M and N are other numerals may be inferred from the following description. Consequently, four keys 221-224, two scan lines S1 and S2 (each having a resistance R_{C}) and two return lines R1 and R2 are illustrated in the key module 220 as shown in FIG. 2. The scan lines S1 and S2 and the return lines R1 and R2 are crossed to each other and respectively coupled to the keys 221-224 so as to form a double cross structure as shown in FIG. 2.

A first terminal of the key 221 and a first terminal of the key 222 are coupled to the scan line S1. A second terminal of the key 221 and a second terminal of the key 222 are coupled to the return line R1 and the return line R2 respectively. A first terminal of the key 223 and a first terminal of the key 224 are coupled to the scan line S2. A second terminal of the key 223 and a second terminal of the key 224 are coupled to the return line R1 and the return line R2 respectively. Besides, the second terminal of the key 221 and the second terminal of the key 223 are coupled to a resistor 281 (having a resistance R_{A}) via the return line R1, and the second terminal of the key 222 and the second terminal of the key 224 are coupled to a resistor 282 (having a resistance R_{A}) via the return line R2. Another end of the resistor 281 and another end of the resistor 282 are coupled to a power terminal V_{DD}.

In the embodiment as shown in FIG. 2, each of the keys 221-224 may include a resistor (having a resistance R_{B}) and a switch _{SW}, wherein the resistor is connected in series with the switch _{SW}. The switch _{SW} of each of the keys (such as the key 221) is turned on in response to the key (the key 221) being pressed, and the switch _{SW} of each of the keys (such as the key 221) is turned off in response to the key (the key 221) not being pressed.

The detection circuit 260 is coupled to the return lines R1 and R2 for detecting return voltages of the return lines R1 and R2, and generates detection signals SD1 and SD2 accordingly so as to indicate that the switch _{SW} of each of the keys 221-224 is at an on state or at an off state.

In the embodiment as shown in FIG. 2, the detection circuit 260 may include two P-type transistors Q21 and Q22. A first terminal of the P-type transistor Q21 is coupled to a ground terminal GND, a control terminal of the P-type transistor Q21 is directly coupled to the corresponding return line R1, and a second terminal of the P-type transistor Q21 may directly generate and output the corresponding detection signal SD1. Similarly, a first terminal of the P-type transistor Q22 is coupled to the ground terminal GND, a control terminal of the P-type transistor Q22 is directly coupled to the corresponding return line R2, and a second terminal of the P-type transistor Q22 may directly generate and output the corresponding detection signal SD2.

The processing circuit 240 is coupled to the detection circuit 260 to receive the detection signals SD1 and SD2, and may determine whether each of the keys 221-224 is actually pressed or not according to the detection signals SD1 and SD2. In an embodiment of the disclosure, the processing circuit 240 may have a pull-up circuit to pull up emitters of the P-type transistors Q21 and Q22 to a high logic level, but the disclosure is not limited thereto. In an embodiment of the disclosure, the processing circuit 240 may be further coupled to the scan lines S1 and S2 to sequentially activate one of the scan lines S1 and S2, and determine whether each key on the activated scan line is pressed or not according to the received detection signals SD1 and SD2.

In an embodiment of the disclosure, the keyboard apparatus 200 may be a membrane keyboard apparatus and the keys 221-224 may be membrane keys, but the disclosure is not limited thereto.

In an embodiment of the disclosure, the P-type transistors Q21 and Q22 may be PNP bipolar junction transistors as shown in FIG. 2, but the disclosure is not limited thereto. In another embodiment of the disclosure, the P-type transistors Q21 and Q22 may also be implemented by using P-type metal oxide semiconductor transistors.

In an embodiment of the disclosure, the processing circuit 240 may be a hardware, a firmware, or a software or a machine-executable program code stored in a memory to be loaded and executed by a microprocessor or by a digital signal processor (DSP). If the processing circuit 240 is implemented by using a hardware, the processing circuit 240 may be realized by a single integrated circuit chip or by a plurality of circuit chips, but the disclosure is not limited thereto. The plurality of circuit chips or the single integrated circuit chip may be implemented by using an application-specific integrated circuit (ASIC) or a field-programmable gate array (FPGA). The memory may be a random access memory, a read-only memory, or a flash memory, for example. In another embodiment of the disclosure, the P-type transistors Q21 and Q22 may be integrated in the processing circuit 240.

In order to correctly determine the actual pressing state of each of the keys 221-224, the P-type transistors Q21 and Q22 in the detection circuit 260 may perform level detection operations on the return voltages of the return lines R1 and R2 respectively. Accordingly, the processing circuit 240 could determine the actual pressing state of each of the keys 221-224. Specifically, when the return voltage of the return line R1 is greater than or equal to a reference voltage, an across voltage between the emitter and a base of the P-type transistor Q21 does not exceed a threshold voltage of the P-type transistor Q21 such that the P-type transistor Q21 is not turned on. At this time, the potential of the detection signal SD1 is at a high logic level, indicating that one of the keys 221 and 223 on the return line R1 is not pressed. Conversely, when the return voltage of the return line R1 is smaller than the reference voltage, the across voltage between the emitter and the base of the P-type transistor Q21 exceeds the threshold voltage of the P-type transistor Q21 such that the P-type transistor Q21 is turned on. At this time, since the P-type transistor Q21 is tuned on, the potential of the detection signal SD1 is the potential of the ground terminal GND, i.e., at a low logic level, thereby indicating that one of the keys 221 and 223 on the return line R1 is pressed. Besides, the operation of the P-type transistor Q22 is similar to the foregoing operation of the P-type transistor Q21, so a repeated description thereof is omitted here. Accordingly, depending on whether the P-type transistor Q21 or the P-type transistor Q22 is turned on or not, the detection signals SD1 and SD2 at different logic levels may be output to indicate whether the corresponding key is pressed or not.

Hereinafter, with reference to FIG. 3, FIG. 3 is a schematic view showing an equivalent circuit of the keyboard apparatus 200 as shown in FIG. 2. Herein the processing circuit 240 is omitted from FIG. 3. As shown in FIG. 3, when the scan line S1 is activated to detect whether the keys 221 and 222 are pressed or not, the voltage applied to the scan line S1 is at a low logic level (such as the potential of the ground terminal GND), and the voltage applied to the scan line S2 is at a high logic level (such as the potential of the power terminal V_{DD}). Similarly, when the scan line S2 is activated to detect whether the keys 223 and 224 are pressed or not, the voltage applied to the scan line S2 is at a low logic level (such as the potential of the ground terminal GND), and the voltage applied to the scan line S1 is at a high logic level (such as the potential of the power terminal V_{DD}). As shown in FIG. 3, when none of the keys 221-224 are pressed, the switches _{SW} in the keys 221-224 are all at an off state. Accordingly, when the scan line S1 is activated, a return voltage V_{R1} of the return line R1 and a return voltage V_{R2} of the return line R2 are both equal to the voltage of the power terminal V_{DD} (greater than or equal to the reference voltage). In this case, the across voltage between the emitter and the base of the P-type transistor Q21 does not exceed the threshold voltage of the P-type transistor Q21, and the across voltage between the emitter and the base of the P-type transistor Q22 does not exceed the threshold voltage of the P-type transistor Q22. As a result, neither of the P-type transistor Q21 and the P-type transistor Q22 is turned on such that the detection signals SD1 and SD2 are both at a high logic level. In this way, the processing circuit 240 determines that the keys 221 and 222 on the scan line S1 are not pressed respectively according to the activated scan line S1 and the detection signals SD1 and SD2 that are at a high logic level. Besides, the detection operation when the scan line S2 is activated is similar to the foregoing detection operation when the scan line S1 is activated, so the foregoing related description may be referred to and repeated details thereof are omitted here.

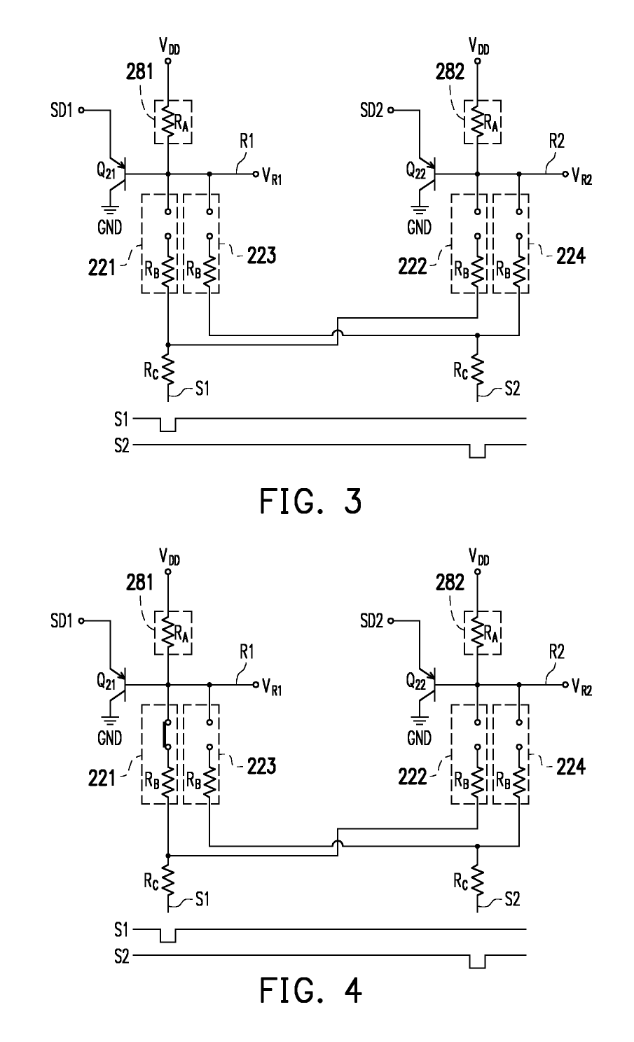

A case where only one key is pressed is described hereinafter. For the purpose of simplifying the contents of the specification, only the case where the key 221 is pressed and the keys 222-224 are not pressed is illustrated here, and other situations may be deduced by analogy. With reference to FIG. 4, FIG. 4 is a schematic view showing an equivalent circuit of the keyboard apparatus in FIG. 3 when the key 221 is pressed. Since only the key 221 is pressed and the other keys 222-224 are not pressed, the switch _{SW} in the key 221 is at an on state, and the switches _{SW} in the keys 222-224 are at an off state. When the scan line S1 is activated, the voltage applied to the scan line S1 is at a low logic level (such as the potential of the ground terminal GND). Accordingly, the return voltage V_{R1} of the return line R1 may be determined by formula (1), and the return voltage V_{R2} of the return line R2 is the voltage of the power terminal V_{DD}.

V_{R1}=V_{DD}×(R_{B}+R_{C})/(R_{A}+R_{B}+R_{C}) formula (1)

In general, the resistance R_{A} may be designed to be exceedingly greater than the resistance R_{B} and the resistance R_{C} such that the return voltage V_{R1} in formula (1) is smaller than the reference voltage. In this way, the across voltage between the emitter and the base of the P-type transistor Q21 exceeds the threshold voltage of the P-type transistor Q21. As a result, the P-type transistor Q21 is turned on to generate the detection signal SD1 that is at a low logic level. Consequently, the processing circuit 240 in FIG. 2 could determine that the key 221 is actually pressed according to the activated scan line S1 and the detection signal SD1 that is at a low logic level. On the other hand, since the return voltage V_{R2} is the voltage of the power terminal V_{DD} (greater than or equal to the reference voltage), the across voltage between the emitter and the base of the P-type transistor Q22 does not exceed the threshold voltage of the P-type transistor Q22. As a result, the P-type transistor Q22 is not turned on, thereby causing the detection signal SD2 to be at a high logic level. In this way, the processing circuit 240 in FIG. 2 could determine that the key 222 is not pressed according to the activated scan line S1 and the detection signal SD2 that is at a high logic level.

Besides, the detection operation when the scan line S2 in FIG. 4 is activated is similar to the foregoing detection operation when the scan line S2 in FIG. 3 is activated, so the foregoing related description may be referred to and repeated details thereof are omitted here.

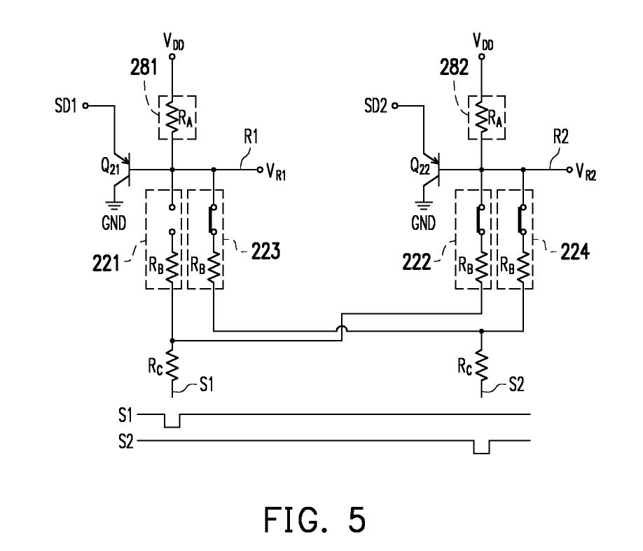

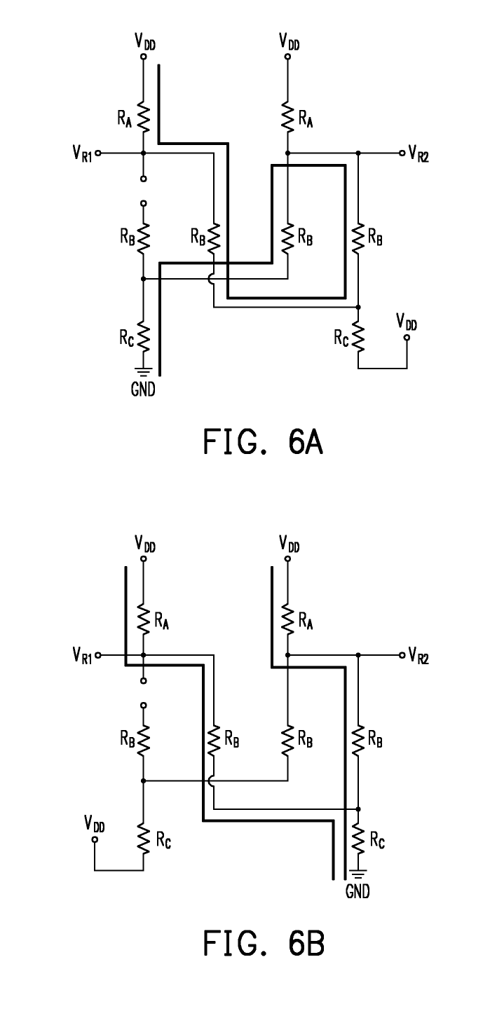

Hereinafter, with reference to FIGS. 5, 6A and 6B together, FIG. 5 is a schematic view showing an equivalent circuit of the keyboard apparatus in FIG. 3 when the keys 222-224 are pressed and the key 221 is not pressed, FIG. 6A is a schematic view showing an equivalent circuit of the keyboard apparatus in FIG. 5 when the scan line S1 in FIG. 5 is activated, and FIG. 6B is a schematic view showing an equivalent circuit of the keyboard apparatus in FIG. 5 when the scan line S2 in FIG. 5 is activated. Herein the P-type transistors Q21 and Q22 are omitted from both FIG. 6A and FIG. 6B. As shown in FIG. 5 and FIG. 6B, when the scan line S2 is activated to detect whether the keys 223 and 224 are pressed, the voltage applied to the scan line S2 is at a low logic level (such as the potential of the ground terminal GND), and the voltage applied to the scan line S1 is at a high logic level (such as the potential of the power terminal V_{DD}). At this time, the return voltages V_{R1} and V_{R2} are respectively expressed by the foregoing formula (1) and the following formula (2). As described above, the return voltages V_{R1} and V_{R2} determined by formula (1) and formula (2) are each smaller than the reference voltage. Consequently, the processing circuit 240 could correctly determine that the keys 223 and 224 are pressed.

V_{R2}=V_{DD}×(R_{B}+R_{C})/(R_{A}+R_{B}+R_{C}) formula (2)

On the other hand, as shown in FIG. 5 and FIG. 6A, when the scan line S1 is activated to detect whether the keys 221 and 222 are pressed, the voltage applied to the scan line S1 is at a low logic level (such as the potential of the ground terminal GND), and the voltage applied to the scan line S2 is at a high logic level (such as the potential of the power terminal V_{DD}). At this time, the return voltage V_{R1} and the return voltage V_{R2} are not the same. Herein the return voltage V_{R2}, due to resistive voltage division, is expressed by the foregoing formula (2), and the return voltage V_{R1}, due to resistive voltage division, is determined by the following formula (3).

V_{R1}=V_{DD}×(3×R_{B}+R_{C})/(R_{A}+3×R_{B}+R_{C}) formula (3)

Therefore, the resistances R_{A}, R_{B} and R_{C} may be properly designed such that the return voltage V_{R1} in formula (3) is greater than or equal to the reference voltage and the return voltage V_{R2} in formula (2) is smaller than the reference voltage. In this way, the processing circuit 240 could correctly determine that the key 221 is not pressed and the key 222 is pressed.

The following should be noted here: by the proper designs of the resistances R_{A}, R_{B} and R_{C} and by the level detection operations of the P-type transistors Q21 and Q22 in the detection circuit 260, the design of the keyboard apparatus from the embodiment of the disclosure may prevent the occurrence of ghost key phenomenon.

In summary, the keyboard apparatus in the embodiment of the disclosure could prevent the occurrence of ghost key phenomenon. Besides, in the keyboard apparatus from the embodiment of the disclosure, for the keyboard apparatus to determine if the key on the return line is pressed or not, only a single transistor is required to perform the level detection operation in each return line. Consequently, it is possible to effectively reduce the manufacturing costs of the keyboard apparatus.

Although the embodiments are already disclosed as above, these embodiments should not be construed as limitations on the scope of the disclosure. It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

1. A keyboard apparatus, comprising:
a key module comprising a plurality of keys, a plurality of scan lines and a plurality of return lines, wherein the plurality of scan lines and the plurality of return lines are crossed to each other and respectively coupled to the plurality of keys; and
a detection circuit coupled to the plurality of return lines for detecting a plurality of return voltages of the plurality of return lines, and generating a plurality of detection signals accordingly so as to indicate that a switch of each of the plurality of keys is at an on state or at an off state,
wherein the detection circuit comprises:
a plurality of P-type transistors, wherein a first terminal of each of the plurality of P-type transistors is coupled to a ground terminal, a control terminal of each of the plurality of P-type transistors is directly coupled to a corresponding one of the plurality of return lines, and a second terminal of each of the plurality of P-type transistors generates and outputs a corresponding one of the plurality of detection signals, wherein only one P-type transistor is configured to detect each return line.

2. The keyboard apparatus as recited in claim 1, wherein each of the plurality of P-type transistors is a PNP bipolar junction transistor.

3. The keyboard apparatus as recited in claim 1, wherein each of the plurality of P-type transistors is a P-type metal oxide semiconductor transistor.

4. The keyboard apparatus as recited in claim 1, wherein:
when the return voltage of the corresponding one of the plurality of return lines is greater than or equal to a reference voltage, the switch of the key coupled between the corresponding one of the plurality of return lines and an activated scan line of the plurality of scan lines is at an off state, wherein the reference voltage is associated with a threshold voltage of the P-type transistor.

5. The keyboard apparatus as recited in claim 1, wherein:
when the return voltage of the corresponding one of the plurality of return lines is smaller than a reference voltage, the switch of the key coupled between the corresponding one of the plurality of return lines and an activated scan line of the plurality of scan lines is at an on state, wherein the reference voltage is associated with a threshold voltage of the P-type transistor.

6. The keyboard apparatus as recited in claim 1, further comprising:
a processing circuit coupled to the detection circuit to receive the plurality of detection signals and determining whether each of the plurality of keys is pressed or not according to the plurality of detection signals.

7. The keyboard apparatus as recited in claim 6, wherein the processing circuit is further coupled to the plurality of scan lines to sequentially activate one of the plurality of scan lines, and determines whether each of the plurality of keys on the activated scan line is pressed or not according to the plurality of detection signals.
